(19) United States
(12) Patent Application Publication
(10) Pub. No.: US 2025/0246476 A1
(43) Pub. Date: Jul. 31, 2025

(54) PROTECTIVE TAPE FOR WAFER GRINDING PROCESS AND METHOD OF MANUFACTURING SEMICONDUCTOR PACKAGE

(71) Applicant: Samsung Electronics Co., Ltd., Suwon-si (KR)

(72) Inventors: Yeonsu SONG, Suwon-si (KR); Sangil CHOI, Suwon-si (KR)

(73) Assignee: Samsung Electronics Co., Ltd., Suwon-si (KR)

(21) Appl. No.: 19/033,836

(22) Filed: Jan. 22, 2025

(30) Foreign Application Priority Data
Jan. 25, 2024 (KR) 10-2024-0011506

(51) Int. Cl. H01L 21/683; B23K 26/53; C09J 7/38; H01L 21/67

(52) U.S. Cl. CPC H01L 21/6836; B23K 26/53; C09J 7/38; H01L 21/67132; C09J 2203/326; H01L 2221/68327; H01L 2221/6834

(57) ABSTRACT

In a method of manufacturing a semiconductor package, a wafer having a first surface and a second surface may be provided; a protective tape for wafer grinding process may be attached on the first surface of the wafer; the wafer having the protective tape attached thereon may be provided on a support member; the second surface of the wafer may be grinded; and the protective tape for wafer grinding process may include a first PSA layer attached on the first surface of a wafer, the first PSA layer having a first elastic modulus, a second PSA layer on the first pressure sensitive layer, the second PSA layer having a second elastic modulus greater than the first elastic modulus, and a plurality of outer layers provided between the support member and the second PSA layer.

### CROSS-REFERENCE TO RELATED APPLICATIONS

This application claims priority under 35 U.S.C. § 119 to Korean Patent Application No. 10-2024-0011506, filed on Jan. 25, 2024, in the Korean Intellectual Property Office (KIPO), the disclosures of which are herein incorporated by reference in their entirety.

### BACKGROUND

### 1. Field

Example embodiments relate to a protective tape for wafer grinding process and/or a method of manufacturing a semiconductor package using the same. More particularly, example embodiments relate to a protective tape for wafer grinding process having a pressure sensitive adhesive (PSA) and/or a method of manufacturing a semiconductor package using the same.

### 2. Description of the Related Art

Semiconductor chips diced by a blade during a sawing process may have uneven cutting surfaces, and thus crack may occur when an external impact is applied to the semiconductor chips. To solve this problem, the grinding after laser (GAL) process, which does not require the sawing process, may be applied. In the GAL process, a laser is irradiated on a wafer to generate a microscopic laser defect, and then a grinding process may be performed such that the semiconductor chips included in the wafer may be finely separated along the microscopic defect during the grinding process. Since the separated semiconductor chips can move horizontally, a corner crack (collision) may occur between the semiconductor chips. Accordingly, it would be beneficial to suppress and/or minimize the horizontal movement of the semiconductor chips during the grinding process.

### SUMMARY

Example embodiments provide a protective tape for wafer grinding process configured to reduce or prevent a corner crack from occurring between semiconductor chips.

Example embodiments provide a method of manufacturing a semiconductor package by using the protective tape.

According to example embodiments, a method of manufacturing a semiconductor package may include attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape having a first PSA (pressure sensitive adhesive) layer, a second PSA layer, and a plurality of outer layers; providing the wafer and the attached protective tape onto a support member; and grinding the second surface of the wafer. The attaching the protective tape may include attaching the first PSA onto the first surface of the wafer such that the first PSA layer is between the wafer and the second PSA layer, and the providing the wafer and the attached protective tape onto the support member may include providing the wafer and the attached protective tape such that the plurality of outer layers is between the support member and the second PSA layer, and the first PSA layer may have a first elastic modulus, and the second PSA layer may have a second elastic modulus greater than the first elastic modulus.

According to example embodiments, a method of manufacturing a semiconductor package may include attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape including a first pressure sensitive adhesive (PSA) layer attached on the first surface of the wafer and a second PSA layer sequentially stacked on the first PSA layer in a vertical direction, the first PSA layer having a first adhesive strength and a first stiffness, and the second PSA layer having a second adhesive strength less than the first adhesive strength and a second stiffness greater than the first stiffness; forming a reforming portion by irradiating a laser onto the scribe lane region of the wafer; and grinding the second surface of the wafer.

According to example embodiments, a method of manufacturing a semiconductor package may include attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape including a first PSA layer and a second PSA layer sequentially stacked in a vertical direction, the first PSA layer being attached on the first surface of the wafer and having a first adhesive strength, a first stiffness, and a first thickness, the second PSA layer being on the first PSA layer and having a second adhesive strength less than the first adhesive strength, a second stiffness greater than the first stiffness, and a second thickness greater than the first thickness; forming a reforming portion by irradiating laser on the scribe lane region of the wafer; and grinding the second surface of the wafer.

According to example embodiments, a protective tape for wafer grinding process may include a first pressure sensitive adhesive (PSA) layer configured to be attached on an active surface of a wafer on which circuits of a plurality of semiconductor chips are formed, the first PSA layer having a first elastic modulus and a first thickness; a second PSA layer on the first pressure sensitive layer, the second PSA layer having a second elastic modulus greater than the first elastic modulus and a second thickness greater than the first thickness; and a plurality of outer layers on the second PSA layer such that the second PSA layer is between the plurality of outer layers and the first PSA layer, the plurality of outer layers including a support layer, a buffer layer, and a coating layer sequentially stacked.

According to example embodiments, a protective tape for wafer grinding process may include an adhesive multilayer, a support layer, a buffer layer, and a coating layer sequentially stacked on an active layer of a wafer. The adhesive multilayer may include a first PSA layer having a relatively greater adhesive strength and a second PSA layer having a relatively greater stiffness.

The first PSA layer may have a first elastic modulus and a first thickness, and the second PSA layer may have a second elastic modulus greater than the first elastic modulus and a second thickness greater than the first thickness.

Accordingly, a stiffness of the second PSA layer may be greater than a stiffness of the first PSA layer, so the second PSA layer may limit movement in a horizontal direction of a plurality of semiconductor chips of the wafer.

Additionally, an adhesive strength of the first PSA layer may be greater than an adhesive strength of the second PSA layer, so the first PSA layer may compensate for the adhesive strength of the second PSA layer. Further, the first thickness of the first PSA layer may be less than the second thickness of the second PSA layer, so the first PSA layer may limit the movement in the horizontal direction of the plurality of semiconductor chips.

### BRIEF DESCRIPTION OF THE DRAWINGS

FIG. 1 is a cross-sectional view illustrating a protective tape for wafer grinding process in accordance with example embodiments.

FIG. 2 is a view illustrating changes in adhesive molecules of a second pressure sensitive adhesive layer of the protective tape in FIG. 1.

FIG. 3 is an experimental graph illustrating a relationship between an adhesive strength, a corner crack, and an elastic modulus of the second pressure sensitive adhesive layer of the protective tape in FIG. 1.

FIGS. 4 to 18 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

Like reference numerals in the drawings denote like components, and sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. It will also be understood that spatially relative terms, such as “above,” “top,” “vertical,” “lateral,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

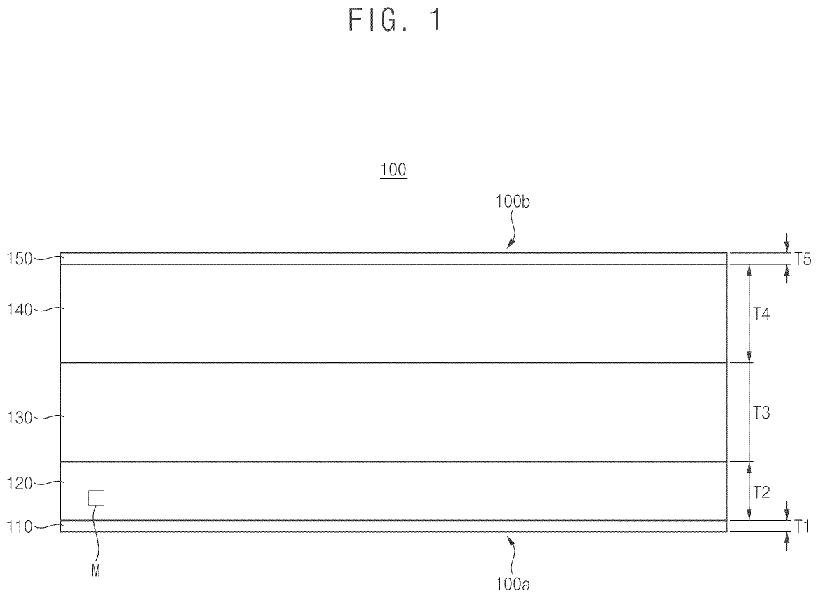

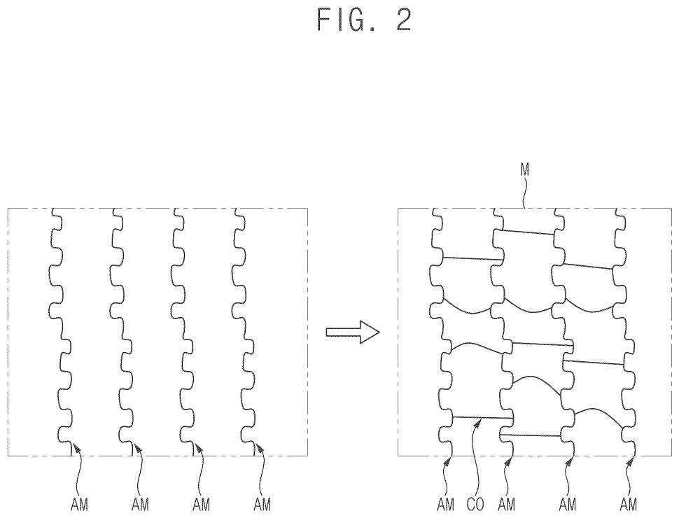

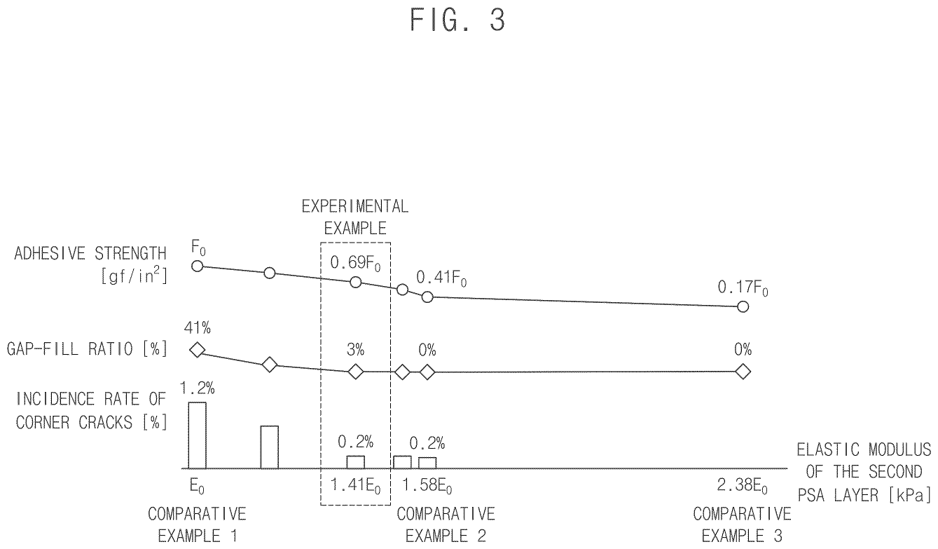

FIG. 1 is a cross-sectional view illustrating a protective tape for wafer grinding process in accordance with example embodiments. FIG. 2 is a view illustrating changes in adhesive molecules of a second pressure sensitive adhesive layer of the protective tape in FIG. 1. FIG. 3 is an experimental graph illustrating a relationship between an adhesive strength, a corner crack, and an elastic modulus of the second pressure sensitive adhesive layer of the protective tape in FIG. 1.

Referring to FIGS. 1 and 2, a protective tape 100 for wafer grinding process may include an adhesive multilayer 110 and 120 and a plurality of outer layers 130, 140, and 150. The adhesive multilayer may include a first pressure sensitive adhesive (PSA) layer 110 configured to be in direct contact with an active surface of a wafer and a second PSA layer 120 provided on the first PSA layer 110. The plurality of outer layers may include a support layer 130, a buffer layer 140, and a coating layer 150 that are sequentially stacked on the second PSA layer 120.

In some example embodiments, the protective tape may be a lamination tape used for a grinding process in which a backside surface of the wafer is partially removed using a grinding wheel. For example, the grinding process may be performed on the backside surface of the wafer. At this time, friction may occur between a front surface of the wafer, which serves as the active surface on which circuits are formed, and a fixing chuck during the grinding process. The front surface of the wafer may be damaged by foreign substances and the friction generated during the grinding process. Accordingly, the lamination tape may be attached onto the front surface of the wafer before the grinding process to protect front surface and the circuits provided on the front surface of the wafer.

In particular, the adhesive multilayer may include a pressure sensitive adhesive (PSA) whose an adhesive strength is generated when pressure is applied thereby bonding and/or increasing the bond of the PSA with a surface. For example, the pressure sensitive adhesive may include an adhesive material and a curing agent.

For example, the adhesive strength and stiffness of the pressure sensitive adhesive may vary depending on a ratio of the adhesive material and the curing agent. The adhesive strength and the stiffness of the pressure sensitive adhesive may be inversely proportional to each other. For example, when a proportion of the curing agent increases, the adhesive strength of the pressure sensitive adhesive may decrease, while the stiffness of the pressure sensitive adhesive may increase. In contrast, when the proportion of the curing agent decreases, the adhesive strength of the pressure sensitive adhesive may increase, while the stiffness of the pressure sensitive adhesive may decrease.

The stiffness may be a property of a specific material to resist an external force when the specific material is subject to the external force. For example, the higher an elastic modulus of a specific material, the stronger may be the stiffness of the specific material. The elastic modulus may be a coefficient that compares the external force applied to a specific material and a degree of deformation of the specific material according to the external force.

The adhesive strength of the pressure sensitive adhesive may be generated by adhesive molecules AM included in the adhesive material of the pressure-sensitive adhesive. For example, the adhesive strength of the pressure-sensitive adhesive may be generated by chemical and mechanical bonding between the adhesive molecules AM and a surface of the wafer. For example, the mechanical bonding may be an anchor effect in which adhesive strength is generated when the adhesive material penetrates a surface of an object to be adhered and hardens.

When the curing agent is mixed with the pressure sensitive adhesive, the curing agent may form cross-links CO connecting the adhesive molecules AM, thereby increasing the stiffness of the pressure sensitive adhesive. However, as an amount of the cross-links CO increases, a proportion of adhesive molecules AM capable of generating the chemical and mechanical bonding with the wafer surface decreases, so the adhesive strength of the pressure sensitive adhesive may decrease. For example, the adhesive multilayers 110 and 120 may include cross-links CO that are formed by the curing agent. In at least some embodiments, a proportion of cross-links CO included in the second PSA layer 120 may be greater than a proportion of cross-links CO included in the first PSA layer 110.

In FIG. 2, the molecules of the adhesive multilayer are illustrated as examples, but this is an example for explanation, the present inventive concept is not limited thereto.

In example embodiments, the first PSA layer 110 may be a layer to be in direct contact with the wafer. For example, the protective tape 100 may be attached to the wafer such that the first PSA layer covers the active surface of the wafer.

The first PSA layer 110 may have a first adhesive strength and a first stiffness. Additionally, the first PSA layer 110 may have a first thickness T1 and a first elastic modulus. The first adhesive strength, the first stiffness, the first thickness T1, and the first elastic modulus may be determined according to an adhesive strength and a possibility of a movement in a horizontal direction of the first PSA layer.

For example, the first PSA layer 110 may have relatively great adhesive strength. In order to maintain the relatively great adhesive strength of the first PSA layer 110, a proportion of a curing agent in the first PSA layer 110 may be relatively low. Accordingly, the first PSA layer 110 may have a relatively low elastic modulus.

For example, the first elastic modulus of the first PSA layer may be within a range of 0.1 kPa to 10 kPa. For example, the first elastic modulus may be a shear storage modulus of the first PSA layer at 20° C.

For example, in case that the first elastic modulus may be above 10 Kpa, the adhesive strength of the first PSA layer may decrease thereby potentially resulting in a peeling phenomenon wherein the protective tape 100 and the wafer are separated from each other. For example, in case that the first elastic modulus is below 0.1 kPa, the stiffness of the first PSA layer may decrease thereby potentially resulting in corner cracks due to an increased likelihood of the plurality of semiconductor chips in contact with the first PSA layer colliding each other in the horizontal direction. Accordingly, when the first elastic modulus of the first PSA layer is within the range of 0.1 kPa to 10 kPa, the peeling phenomenon in which the protective tape 100 and the wafer are separated from each other may be prevented, and the corner cracks between the plurality of semiconductor chips may be prevented.

The first PSA layer 110 may have a relatively thin thickness. For example, the first thickness T1 may be within a range of 1 micrometer (μm) to 5 μm. For example, in case that the first thickness of the first PSA layer is above 5 μm, the corner crack may occur. For example, in case that the first thickness of the first PSA layer is below 1 μm, the first thickness of the first PSA layer may be uneven due to limitations in manufacturing tolerances in the process. Accordingly, when the first thickness of the first PSA layer is within the range of 1 μm to 5 μm, the first PSA layer may be evenly provided on the protective tape 100, and the corner cracks may be prevented.

For example, the greater the first thickness of the first PSA layers, the greater a movement in the horizontal direction of the first PSA layer may be. For example, a deformation in the horizontal direction of the first PSA layer may be proportional to a magnitude of the external force exerted on the first PSA layer in the horizontal direction and the first thickness of the first PSA layer, and the deformation in the horizontal direction of the first PSA layer may be inversely proportional to the first elastic modulus of the first PSA layer. Accordingly, the first PSA layer, which has a relatively low elastic modulus, may have a relatively thin thickness in order to facilitate the mitigation and/or prevention of the movement in the horizontal direction.

In example embodiments, the second PSA layer 120 may be stacked on the first PSA layer 110. For example, the second PSA layer 120 may be a layer with relatively high stiffness to limit the horizontal movement of a plurality of semiconductor chips in contact with the protective tape 100. For example, a stiffness of the second PSA layer 120 may have higher than the stiffness of the first PSA layer 110. In at least some example embodiments, a deformation of the second PSA layer in the horizontal direction may be proportional to a magnitude of the external force exerted on the second PSA layer in the horizontal direction and the thickness of the second PSA layer, and the deformation of the second PSA layer in the horizontal direction may be inversely proportional to the elastic modulus of the second PSA layer.

The second PSA layer 120 may have a second adhesive strength less than the first adhesive strength and a second stiffness greater than the first stiffness. Additionally, the second PSA layer 120 may have a second thickness T2 greater than the first thickness T1 and a second elastic modulus greater than the first elastic modulus. The second adhesive strength, the second stiffness, the second thickness T2, and the second elastic modulus may be determined according to the adhesive strength of the second PSA layer and the possibility of movement in the horizontal direction.

For example, the second PSA layer 120 may have relatively high stiffness. In order to maintain relatively strong stiffness, the second PSA layer 120 may have a relatively high proportion of the curing agent. Accordingly, the second PSA layer 120 may have a relatively high elastic modulus.

For example, the second elastic modulus of the second PSA layer may be within a range of 100 KPa to 1000 KPa. For example, the second elastic modulus may be a shear storage modulus of the second PSA layer at 20° C.

For example, in case that the second elastic modulus is above 1000 Kpa, it may be difficult for the adhesive multilayers 110 and 120 of the protective tape 100 to follow a curvature of the surface of the wafer, so the adhesive strength of the first PSA layer 110 may be reduced. Accordingly, a peeling phenomenon in which the protective tape 100 and the wafer are separated from each other may occur (e.g., due to poor contact between the first PSA layer 110 and the wafer). For example, in case that the second elastic modulus is below 100 Kpa, the stiffness of the second PSA layer may decrease thereby potentially resulting in cause corner cracks due to an increased likelihood of a plurality of semiconductor chips in contact with the protective tape 100 colliding in the horizontal direction.

For example, the second thickness T2 may be within a range of 10 μm to 25 μm. For example, in case that the second thickness of the second PSA layer is above 25 μm, the likelihood of corner cracks occurring may increase. For example, in case that the second thickness of the second PSA layer is below 10 μm, it may be difficult for the adhesive multilayers 110 and 120 of the protective tape 100 to follow a curvature of the surface of the wafer, so the adhesive strength of the first PSA layer 110 may be decreased. Accordingly, a peeling phenomenon in which the protective tape 100 and the wafer are separated from each other may occur. Therefore, in case that the second thickness of the second PSA layer is within the range of 10 μm to 25 μm, the peeling phenomenon between the protective tape 100 and the wafer may be prevented, and the corner cracks between a plurality of semiconductor chips may be prevented.

For example, the second PSA layer 120 may include an adhesive material and a curing agent. For example, the curing agent may include a thermosetting agent. For example, the second PSA layer may include an acrylate polymer-based adhesive material and an isocyanate-based curing agent. For example, the second PSA layer 120 may include 0.5% to 5.0% by weight of the isocyanate-based curing agent based on a total weight of the second PSA layer.

For example, in case that the second PSA layer includes above 5.0% by weight of the curing agent, it may be difficult for the adhesive multilayers 110 and 120 of the protective tape 100 to follow a curvature of the surface of the wafer, so the adhesive strength of the first PSA layer 110 may decrease. Accordingly, a peeling phenomenon in which the protective tape 100 and the wafer are separated from each other may occur. For example, in case that the second PSA layer include below 0.5% by weight of the curing agent, the stiffness of the second PSA layer may decrease, so corner cracks may occur in which a plurality of semiconductor chips in contact with the protective tape 100 collide in the horizontal direction. Thus, when the second PSA layer may include the curing agent in the range of 0.5% by weight to 5.0% by weight, the peeling phenomenon between the protective tape 100 and the wafer may be prevented, and the corner cracks may be prevented.

Additionally, the first PSA layer 110 may include an adhesive material and a curing agent. For example, the curing agent may include a thermosetting agent. For example, the first PSA layer may include an acrylate polymer-based adhesive material and an isocyanate-based curing agent. For example, in order for the first PSA layer to have high adhesive, the proportion of the curing agent may be relatively very low. For example, the proportion of the curing agent included in the first PSA layer may be less than the proportion of the curing agent included in the second PSA layer. In at least some embodiments, the first PSA layer 110 and the second PSA layer 120 may include different ratios of the same and/or substantially similar materials. Therefore, a bond between the first PSA layer 110 and the second PSA layer 120 may be ensured due to the similarities in material, thereby resulting in an adhesive multilayer with good adhesion and good stiffness.

In example embodiments, the support layer 130 may be stacked on the second PSA layer 120. For example, the support layer may be provided as a middle layer of the protective tape 100 and may be a structure that supports an overall shape of the protective tape 100. For example, the support layer may include polyethylene terephthalate. For example, a thickness T3 of the support layer may be within a range of 40 μm to 60 μm.

In example embodiments, the buffer layer 140 may be provided on the support layer 130 to buffer the support layer 130 provided below the buffer layer and a layer provided above the buffer layer 140. For example, the buffer layer 140 may include at least one of polyurethane, polyolefin, and oriented polypropylene. For example, a thickness T4 of the buffer layer may be within a range of 40 μm to 60 μm.

In example embodiments, the coating layer 150 may be proved on the buffer layer 140 such that the coating layer 150 faces a fixing chuck of a grinding processing apparatus during a grinding process. For example, the coating layer may be an outermost layer that is exposed to the outside when the protective tape 100 is attached to the active surface of the wafer. For example, a thickness T5 of the coating layer may be within a range of 1 μm to 5 μm.

For example, in at least some embodiments, the support layer 130 may be referred to as having a third thickness T3 greater than the second thickness T2 of the second PSA layer; the buffer layer 140 may be referred to as having a fourth thickness T4 greater than the second thickness T2; and the coating layer 150 may be referred to as having a fifth thickness T5 less than the second thickness T2.

In at least some example embodiments, stiffness of each of the support layer 130, the buffer layer 140, and the coating layer 150 may greater than the stiffness of each of the first and second PSA layers 110 and 120 in order to maintain a shape of the protective tape 100.

Referring to FIG. 3, a graph illustrates that changes in adhesive strength, gap-fill ratio, and incidence rate of corner cracks with respect to the second elastic modulus of the second PSA layer. For example, the second elastic modulus may be an indentation modulus. For example, the indentation modulus may be calculated by comparing an externally applied load and a displacement of the protective tape. For example, a load may be applied in a direction perpendicular to the protective tape.

In the graph, the adhesive strength may represent the adhesive strength between the protective tape 100 and the wafer. Accordingly, as the adhesive strength decreases, a peeling phenomenon may occur between the protective tape 100 and the wafer. Additionally, the gap-fill ratio may represent the extent to which the protective tape 100 fills a scribe lane region of the wafer. Accordingly, as the adhesive strength increases, the gap-fill ratio may increase. Additionally, the incidence rate of corner cracks may be a proportion of a number of semiconductor chips in which corner cracks occur to a total number of a plurality of semiconductor chips included in the wafer.

Comparative example 1 may represents an experimental example that serves as a standard for comparison. In comparative example 1, an elastic modulus of the second PSA layer may be ‘E0’. In comparative example 1, since the modulus of elasticity of the second PSA layer is relatively low, an adhesive strength and gap-fill ratio of the protective tape 100 may be relatively high. For example, in comparative example 1, the adhesive strength of the protective tape 100 may be ‘F0’, and the gap-fill ratio of the protective tape 100 may be 41%. Additionally, because the elastic modulus of the second PSA layer is relatively low, incidence rate of corner cracks may be relatively high. For example, the incidence rate of corner cracks may be 1.2%.

Comparative example 2 may be an experimental example for comparison with an experimental example having an different numerical range. In comparative example 2, the elastic modulus of the second PSA layer may be ‘1.58 E0’. In comparative example 2, since the elastic modulus of the second PSA layer is relatively high, the adhesive strength and gap-fill ratio of the protective tape 100 may be relatively low. For example, in comparative example 2, the adhesive strength of the protective tape 100 may be ‘0.41 F0’, and the gap-fill ratio of the protective tape 100 may be ‘0%’. Thereby increasing the likelihood of a peeling phenomenon. However, because the elastic modulus of the second PSA layer is relatively high, an incidence rate of corner cracks may be relatively low, e.g., in cases wherein the peeling phenomenon does not occur. For example, the incidence rate of corner cracks may be ‘0.2%’.

Comparative example 3 may be an experimental example for comparison with experimental examples having a third numerical range. In comparative example 3, the elastic modulus of the second PSA layer may be ‘2.38 E0’. In comparative example 3, since the elastic modulus of the second PSA layer is relatively high, the adhesive strength and gap-fill ratio of the protective tape 100 may be relatively low. Thereby increasing the likelihood of a peeling phenomenon. However, in comparative example 3, the adhesive strength of the protective tape 100 may be ‘0.17 F0’, and the gap-fill ratio of the protective tape 100 may be ‘0%’. Additionally, because the elastic modulus of the second PSA layer is relatively high, the incidence rate of corner cracks may be relatively low, e.g., in cases wherein the peeling phenomenon does not occur. For example, the incidence rate of corner cracks may be ‘0%’.

Comparing the experimental example with comparative example 1 and comparative example 2, an elastic modulus of the second PSA layer of the experimental example may be greater than the elastic modulus of the second PSA layer of comparative example 1, and may be less than the elastic modulus of the second PSA layer of comparative example 2. For example, the elastic modulus of the second PSA layer of the experimental example may be ‘1.41 E0’. In addition, an adhesive strength of the protective tape 100 of the experimental example may be less than the adhesive strength of the protective tape 100 of comparative example 1, and may be greater than the adhesive strength of the second PSA layer of comparative example 2. For example, the adhesive strength of the protective tape 100 in the experimental example may be ‘0.69 F0’. In addition, a gap-fill ratio of the protective tape 100 in the experimental example may be less than the gap-fill ratio of the protective tape 100 in comparative example 1, and may be greater than the gap-fill ratio of the second PSA layer in comparative example 2. For example, the gap-fill ratio of the protective tape 100 in the experimental example may be ‘3%’.

Comparing comparative example 1 and experimental example, in case that the elastic modulus of the second PSA layer of the protective tape 100 is relatively low, that is, in case that the stiffness of the protective tape 100 is relatively low, corner cracks may increase because a movement in horizontal direction of the protective tape 100 increases during the grinding process. In addition, comparing comparative example 2 and experimental example, in case that the elastic modulus of the second PSA layer of the protective tape 100 is relatively high, that is, in case that the stiffness of the protective tape 100 is relatively high, the peeling phenomenon between the protective tape 100 and the wafer may occur during the grinding process because the adhesive strength between the protective tape 100 and the wafer is insufficient.

As described above, the protective tape 100 for wafer grinding process may include the adhesive multilayer 110 and 120, the support layer 130, the buffer layer 140, and the coating layer 150 that are sequentially stacked on the active surface of the wafer. The adhesive multilayer may include the first PSA layer 110 having a relatively great adhesive strength to be attached to the active surface of the wafer, and the second PSA layer 120 that is configured to minimize a movement in the horizontal direction of each of the plurality of semiconductor chips included in the wafer.

The first PSA layer 110 may have the first elastic modulus G1 and the first thickness T1, and the second PSA layer 120 may have the second elastic modulus G2 and the second thickness T2. The second elastic modulus G2 may be greater than the first elastic modulus G1, and the second thickness T2 may be greater than the first thickness T1.

Accordingly, since the second PSA layer 120 may have relatively high stiffness, the second PSA layer 120 may limit a movement in the horizontal direction of the plurality of semiconductor chips of the wafer.

Additionally, since the first PSA layer 110 may have a relatively high adhesive strength, first PSA layer 110 may compensate for the adhesive strength of the second PSA layer 120. Further, since the first thickness T1 of the first PSA layer 110 is less than the second thickness T2 of the second PSA layer 120, the first PSA layer 110 may limit the movement in the horizontal direction of the plurality of semiconductor chips of the wafer.

Hereinafter, a method of manufacturing a semiconductor package using the protective tape 100 according to example embodiments will be described.

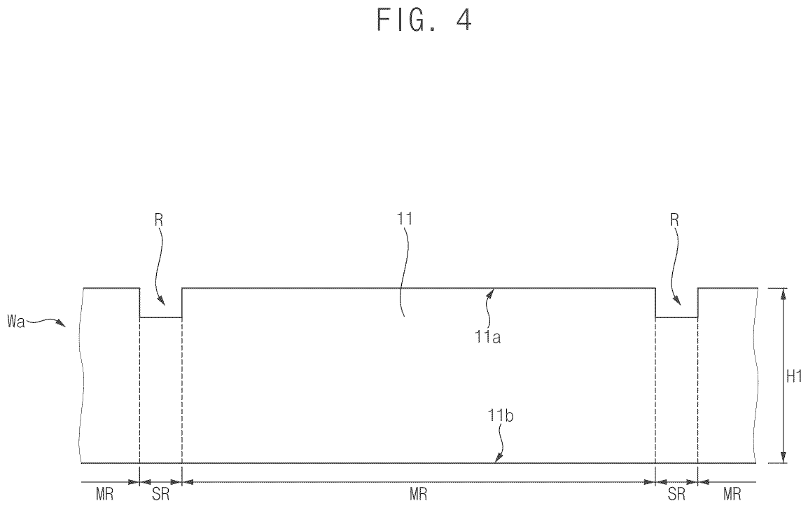

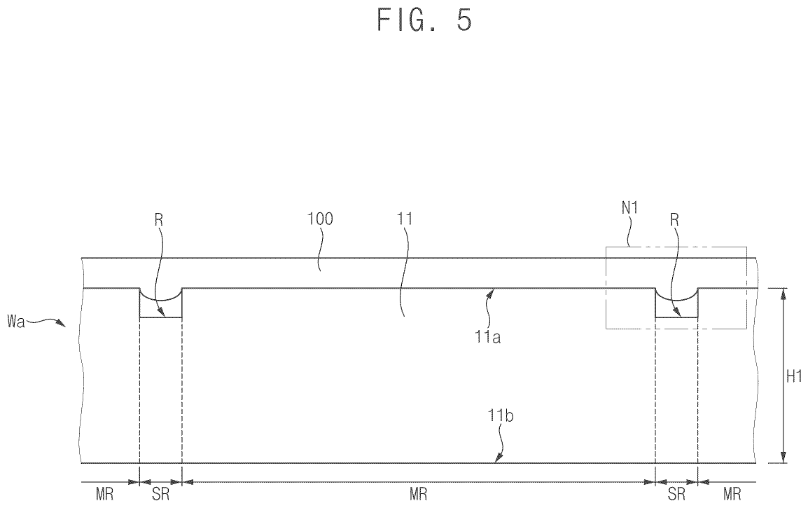

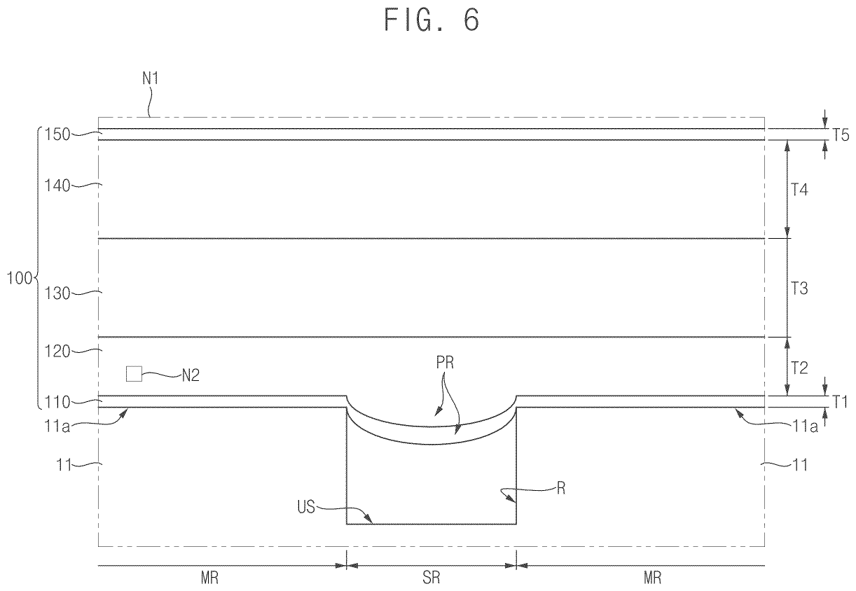

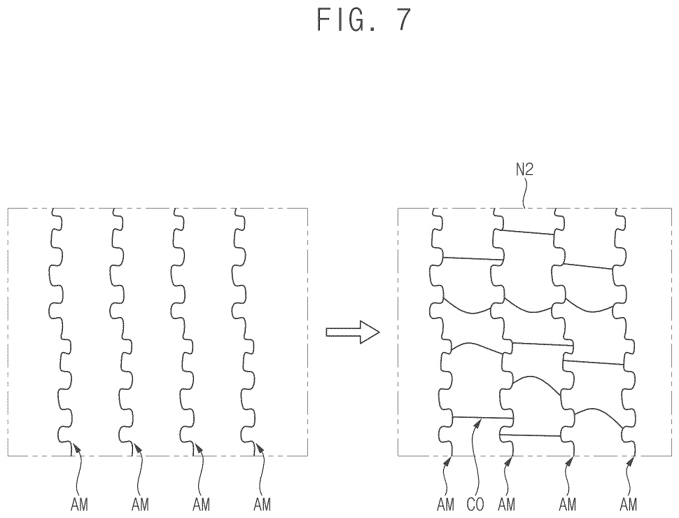

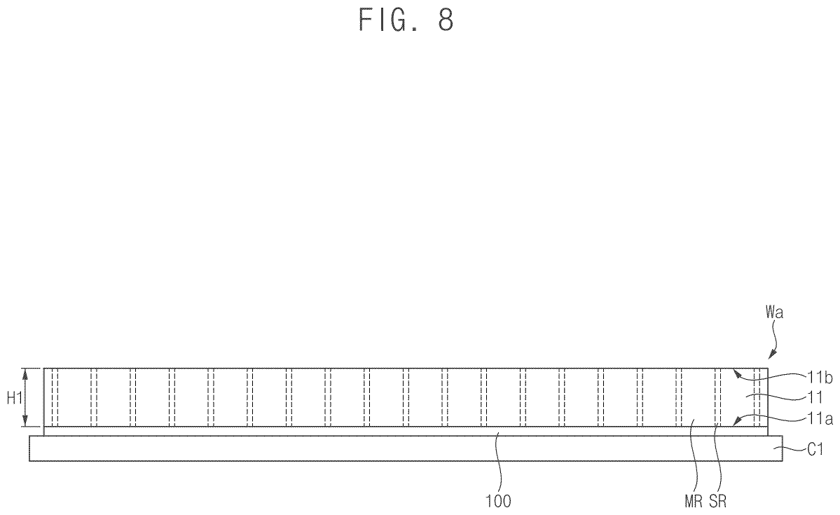

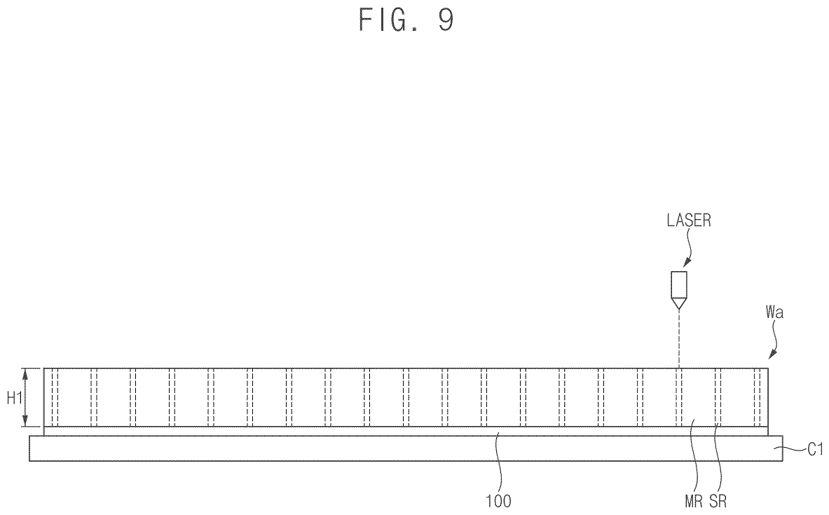

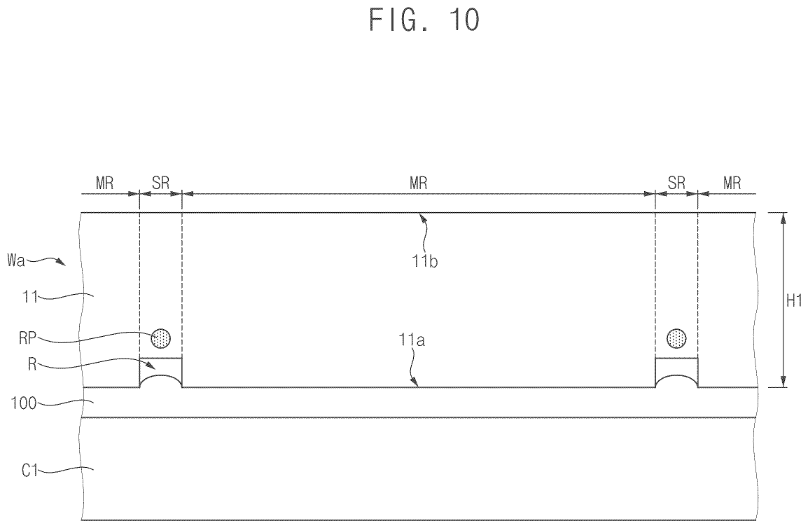

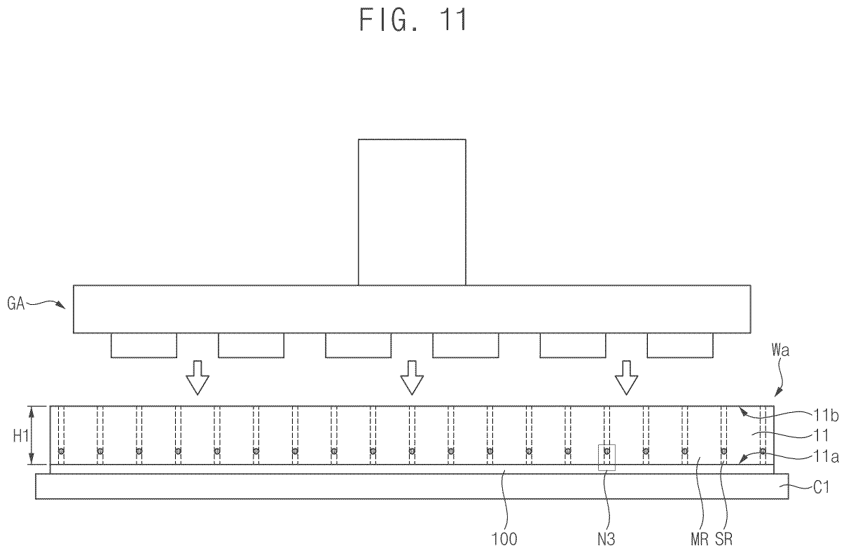

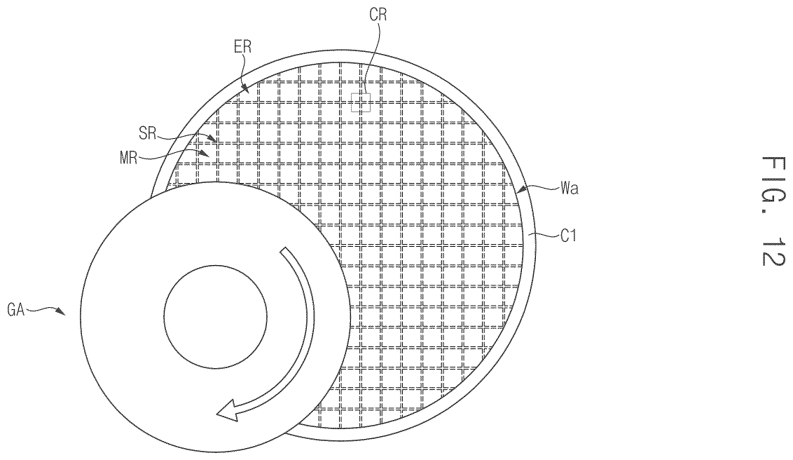

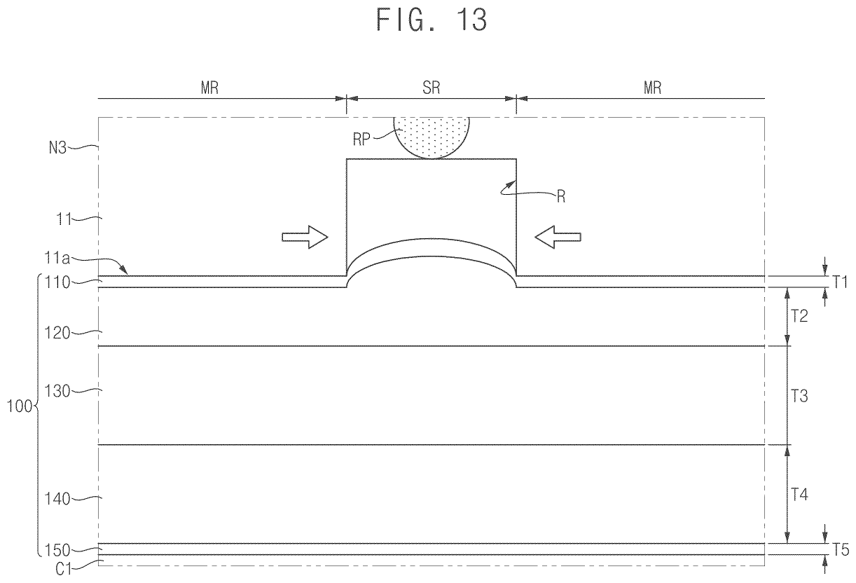

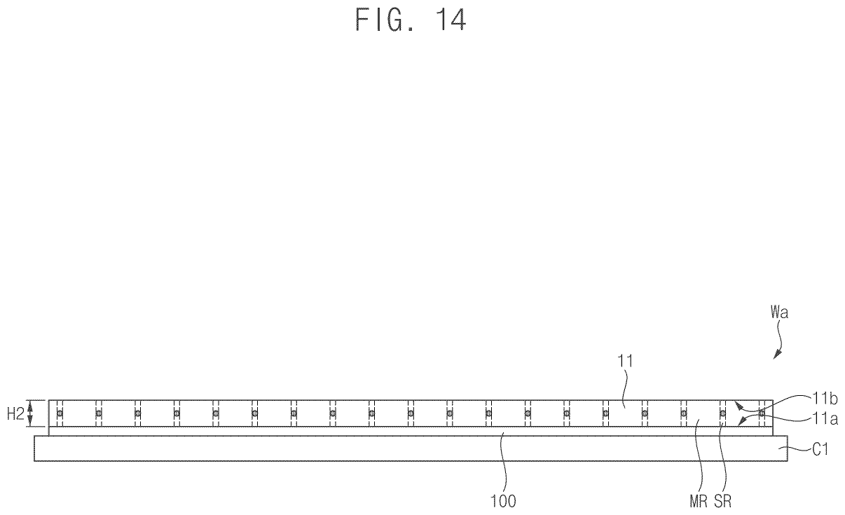

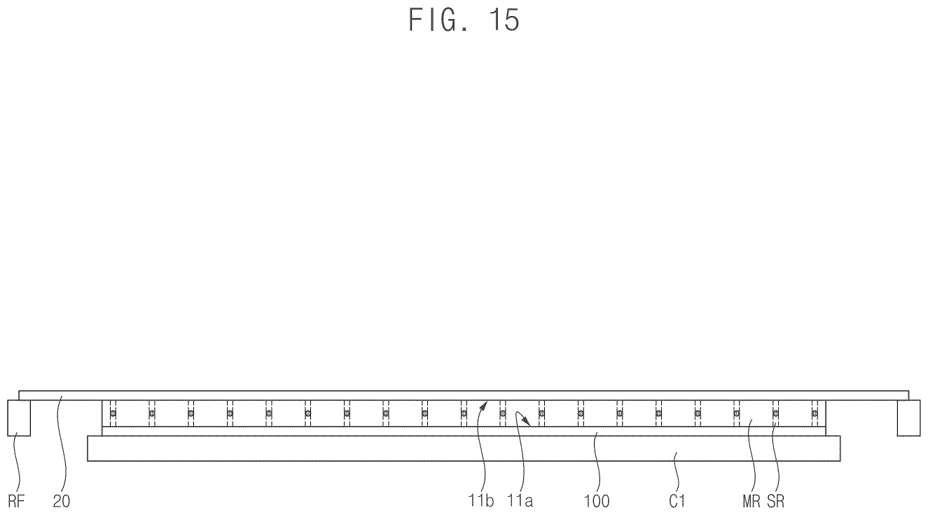

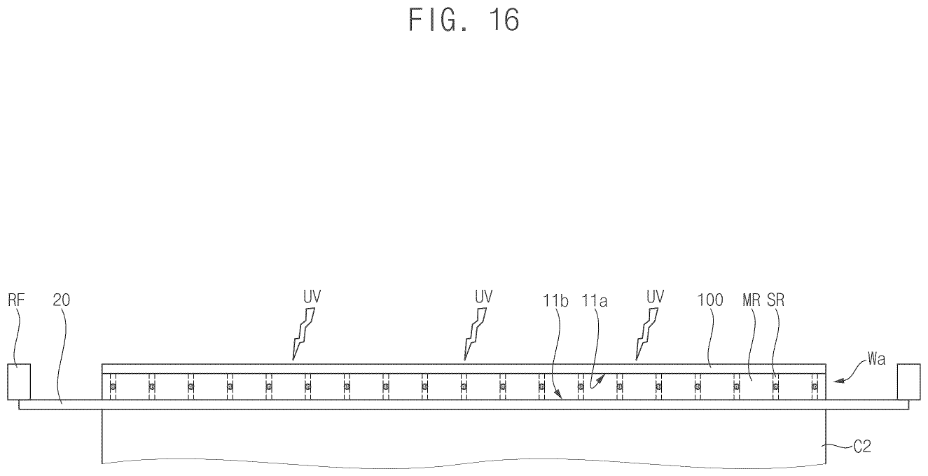

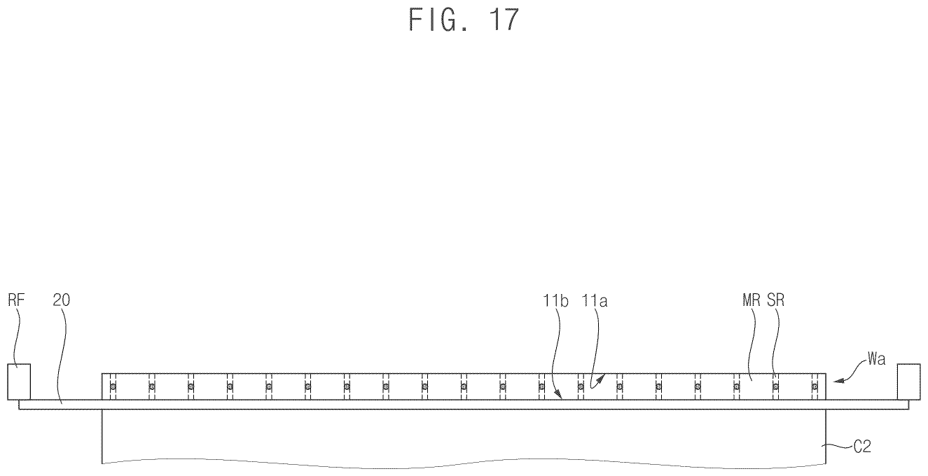

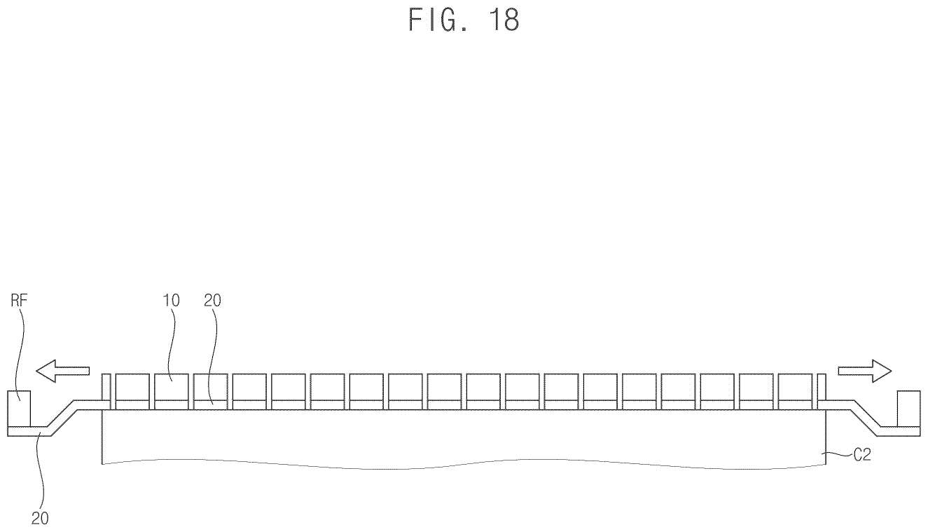

FIG. 4 is a cross-sectional view illustrating a wafer in accordance with example embodiments. FIG. 5 is a cross-sectional view illustrating a wafer on which a protective tape for wafer grinding process in accordance with example embodiments is attached. FIG. 6 is an enlarged cross-sectional view illustrating portion ‘N1’ of FIG. 5. FIG. 7 is an enlarged cross-sectional view illustrating portion ‘N2’ of FIG. 6. FIG. 8 is a cross-sectional view illustrating the wafer provided on a support member. FIG. 9 is a cross-sectional view illustrating that laser is irradiated on the wafer. FIG. 10 is an enlarged cross-sectional view illustrating that a reforming portion is formed on the wafer through a laser process. FIG. 11 is a cross-sectional view illustrating that a grinding process is performed on the wafer. FIG. 12 is a plan view illustrating that a grinding process is performed on the wafer. FIG. 13 is an enlarged cross-sectional view illustrating portion ‘N3’ of FIG. 11. FIG. 14 is a cross-sectional view illustrating that the grinding process is completed on the wafer. FIG. 15 is a cross-sectional view illustrating that a ring frame is attached on the wafer to move the wafer. FIG. 16 is a cross-sectional view illustrating light is irradiated on the wafer. FIG. 17 is a cross-sectional view illustrating that the protective tape for wafer grinding process in accordance with example embodiments is removed. FIG. 18 is a cross-sectional view illustrating that the wafer is separated into a plurality of semiconductor chips.

Referring to FIG. 4, a wafer Wa may be provided, the wafer including a plurality of chip mounting regions MR and a scribe lane region SR between and/or surrounding the plurality of chip mounting regions MR. For example, the plurality of chip mounting regions MR may be individualized into a plurality of semiconductor chips by being separated along the scribe lane region SR.

For example, the wafer Wa may include a substrate 11 having a first surface 11a and a second surface 11b opposite to the first surface, each extending in a horizontal direction. For example, the first surface may be an active surface on which circuits are formed on the plurality of chip mounting regions MR, and the second surface may be an inactive surface on which circuits are not formed.

For example, the wafer Wa may be provided with a recess R on the scribe lane region SR, the recess having a certain depth and being configured to divide the plurality of chip mounting regions MR.

For example, the wafer Wa may have a first height H1. For example, the first height H1 may be a height of the wafer before grinding processing. For example, the first height may be within a range of 750 μm to 800 μm.

Referring to FIGS. 5 to 7, a protective tape 100 for wafer grinding process may be provided, and the protective tape 100 may be attached onto the first surface 11a (e.g., the active surface) of the wafer Wa. For example, the protective tape may be a lamination tape used in a grinding process as discussed above. For example, the protective tape may be a structure to mitigate and/or prevent the circuits of the wafer from being damaged during the grinding process.

First, a protective tape 100 for wafer grinding process may be provided.

Since the protective tape is substantially the same as the protective tape 100 in accordance with the example embodiments described in FIGS. 1 and 3, repeated descriptions of the same components will be omitted.

Thereafter, the protective tape 100 may be attached onto the wafer Wa so that the first PSA layer 110 of the protective tape 100 faces the first surface 11a of the wafer Wa.

For example, the protective tape 100 may be attached onto the wafer Wa such that the protective tape 100 and the wafer Wa are integrally combined by applying pressure on the coating layer 150 of the protective tape 100. For example, since the first PSA layer 110 has a relatively high adhesive strength, the first PSA layer 110 may be chemically (e.g., through physical bonds such as hydrogen and/or van der Waal bonds between unreacted cross-links and dangling bonds on the wafer Wa) and/or mechanically bonded with the first surface 11a of the wafer Wa.

For example, a protrusion PR protruding toward the recess R of the wafer Wa may be formed when the protective tape 100 is attached onto the wafer Wa. For example, stiffness of the first PSA layer and the second PSA layer may be less than a stiffness of the plurality of outer layers 130, 140, and 150, so the first PSA layer and the second PSA layer may be easily deformed to form the protrusion. However, since the second PSA layer has relatively high stiffness, the protrusion may be in not contact with an exposed surface US of the recess.

Referring to FIGS. 8 to 10, the wafer Wa may be provided on the first support member C1 so that the protective tape 100 faces the first support member C1 (e.g., is between the first support member C1 and the wafer Wa), and a laser may be irradiated on the scribe lane region SR of the wafer Wa to form a plurality of reforming portions RP.

For example, the reforming portion RP may be a portion that brittleness increases by irradiating laser. Herein, brittleness may be the property of being easily broken when an external force is applied to a specific material. For example, the reforming portions may be a portion configured to facilitate a process of individualizing the wafer into a plurality of semiconductor chips.

For example, the first support member may be a chuck table configured to secure the wafer provided on the first support member by using a pressure difference.

Referring to FIGS. 11 to 14, the second surface as an inactive surface 11b of the wafer Wa may be ground, e.g., by using a grinding wheel GA.

For example, the wafer Wa may be provided that the first surface 11a of the wafer Wa faces the first support member C1. Thereafter, the wafer Wa may be partially removed by using a grinding wheel GA that is rotated in a certain direction. For example, a portion the wafer Wa may be removed from the second surface 11b (e.g., the inactive surface) of the wafer Wa to a predetermined height. For example, a height of the wafer after the grinding process may have a second height H2. For example, the second height may be within a range of 30 μm to 60 μm.

The wafer Wa may include an outer region ER and a corner region CR. The outer region ER may be a region where a plurality of outermost semiconductor chips of the wafer Wa are provided, and the corner region CR may be a region where the plurality of semiconductor chips are adjacent to each other. The first PSA layer 110 having a first adhesive strength may prevent a peeling phenomenon that the plurality of outermost semiconductor chips on the outer region (ER) are separated from the protective tape 100 during the grinding process. Additionally, the second PSA layer 120 having a second stiffness may mitigate and/or prevent corner cracks from forming. The corner cracks may otherwise occur due to collisions between the plurality of adjacent semiconductor chips on the corner region CR during the grinding process.

Referring again to FIG. 13, the protective tape 100 may be disposed between the first support member C1 and the wafer Wa. During the grinding process, an external force in the horizontal direction may be applied to the wafer Wa from the grinding wheel GA. Additionally, since the wafer Wa includes the plurality of reforming portions RP on the scribe lane RP, the plurality of reforming portions RP may be vulnerable to the external force.

Since the second PSA layer 120 of the protective tape 100 has relatively high stiffness, the second PSA layer 120 may minimize a movement in the horizontal direction of the plurality of semiconductor chips of the wafer Wa during the grinding process. Accordingly, the second PSA layer 120 may prevent the corner cracks.

Since the first PSA layer 110 of the protective tape 100 has a relatively high adhesive strength, the first PSA layer 110 may compensate for the relatively low adhesive strength of the second PSA layer 120. Accordingly, the peeling phenomenon of the first PSA layer 110 may be prevented.

Referring to FIG. 15, the wafer Wa may be moved by attaching an adhesive film 20 configured to integrally couple the wafer Wa and the ring-frame RF on the second surface 11b of the wafer.

For example, the wafer Wa may be provided on the adhesive film 20. First, the adhesive film 20 may be attached on the ring frame RF, and then the wafer Wa may be attached on the adhesive film 20. For example, the ring frame RF may have an annular shape. A peripheral portion of the adhesive film 20 may be attached on one side portion of the ring frame RF. The ring frame RF may support the adhesive film 20 and may serve as a carrier frame to support the wafer during a substrate processing process.

For example, the adhesive film 20 may be a structure that integrally couples the wafer Wa with the ring frame RF during processes. Additionally, the adhesive film 20 may be an adhesive configure to sequentially stack the plurality of semiconductor chips included in the wafer Wa on a package substrate after the plurality of semiconductor chips are individualized. For example, the adhesive film may be a die attach film (DAF).

Referring to FIGS. 16 and 17, the wafer Wa may then be provided on a second support member C2, and a protective tape 100 may be cured and then removed by irradiating light on the protective tape 100 attached on the first surface 11a of the wafer Wa. For example, the light is ultraviolet rays UV.

For example, the first PSA layer 110 may include a material that hardens when irradiated with ultraviolet rays UV. For example, in least some embodiments, a curing agent may be activated by the ultraviolet rays UV, thereby increasing the stiffness and lowering the adhesiveness of the first PSA layer 110. Accordingly, the first PSA layer 110 may be cured by irradiating ultraviolet rays UV on the protective tape 100 attached to the wafer Wa. Thereafter, the protective tape 100 may be removed from the wafer Wa.

For example, the second support member may be a chuck table configured to secure the wafer provided on the second support member using a pressure difference.

Referring to FIG. 18, after cooling the adhesion film 20, the adhesion film 20 may be expanded to individualize the wafer Wa into a plurality of semiconductor chips 10. For example, a portion of the adhesive film 20 may remain on the plurality of semiconductor chips. The portion of the adhesive film 20 may serve to sequentially attach the plurality of semiconductor chips on the package substrate. For example, the adhesive film may be rapidly cooled by using liquid nitrogen.

Although not illustrated in the figures, and then the plurality of individualized semiconductor chips may then be stacked on a package substrate, and the plurality of semiconductor chips and the package substrate may be electrically connected by using a plurality of wires, and a molding member may be formed to cover the semiconductor chips and the plurality of wires, so the semiconductor package may be completed.

As described above, in the method of manufacturing a semiconductor package according to example embodiments, the wafer Wa may be provided, wherein the wafer having the first surface as active surface 11a and the second surface as inactive surface 11b facing each other. The protective tape 100 for wafer grinding process may be attached on the first surface 11a of the wafer Wa. Then, the wafer Wa may be located on the first support member C1 so that the first surface 11a of the wafer faces the first support member C1, and the wafer Wa may be ground from the second surface 11b of the wafer through a grinding process.

The protective tape 100 for wafer grinding process may include the adhesive multilayer 110 and 120 sequentially stacked on the active surface of the wafer. The adhesive multilayer may include the first PSA layer 110 having a relatively great adhesive strength to be attached to the active surface of the wafer, and the second PSA layer 120 configure to minimize a movement in the horizontal direction of each of the plurality of semiconductor chips of the wafer. The first PSA layer 110 may have the first elastic modulus G1 and the first thickness T1, and the second PSA layer 120 may have the second elastic modulus G2 and the second thickness T2. The second elastic modulus G2 may be greater than the first elastic modulus G1, and the second thickness T2 may be greater than the first thickness T1.

Accordingly, since the first PSA layer 110 and the second PSA layer 120 may limit a movement in the horizontal direction of the plurality of semiconductor chips of the wafer, the first PSA layer 110 and the second PSA layer 120 can prevent the corner cracks that collide between the plurality of semiconductor chips during the grinding process.

Additionally, since the first PSA layer 110 may compensate for the adhesive strength of the second PSA layer 120, the first PSA layer 110 may reduce the potential for and/or prevent the plurality of semiconductor chips provided on the wafer Wa and the protective tape 100 from being separated during semiconductor manufacturing processes.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A method of manufacturing a semiconductor package, the method comprising:
attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape having a first PSA (pressure sensitive adhesive) layer, a second PSA layer, and a plurality of outer layers;
providing the wafer and the attached protective tape onto a support member; and
grinding the second surface of the wafer,
wherein attaching the protective tape includes attaching the first PSA onto the first surface of the wafer such that the first PSA layer is between the wafer and the second PSA layer,
wherein providing the wafer and the attached protective tape onto the support member includes providing the wafer and the attached protective tape such that the plurality of outer layers is between the support member and the second PSA layer, and
wherein the first PSA layer has a first elastic modulus, and the second PSA layer has a second elastic modulus greater than the first elastic modulus.

2. The method of claim 1, wherein the first PSA layer has a first thickness, and the second PSA layer has a second thickness greater than the first thickness.

3. The method of claim 2, wherein the first thickness is within a range of 1 μm to 5 μm, and the second thickness is within a range of 10 μm to 25 μm.

4. The method of claim 1, wherein the second PSA layer includes an isocyanate-based curing agent.

5. The method of claim 4, wherein the second PSA layer includes 0.5% by weight to 5% by weight of the isocyanate-based curing agent based on a total weight of the second PSA layer.

6. The method of claim 1, wherein the first elastic modulus and the second elastic modulus are each a shear storage modulus.

7. The method of claim 6, wherein the first elastic modulus is within a range of 0.1 kilopascal (kPa) to 10 kPa, and the second elastic modulus is within a range of 100 kPa to 1000 kPa.

8. The method of claim 1, further comprising:
forming a reforming portion before grinding the wafer,
wherein forming the reforming portion includes irradiating a laser on the scribe lane region of the wafer.

9. The method of claim 8, further comprising:
debonding the protective tape from the wafer by curing the first PSA layer after forming the reforming portion,
wherein curing the first PSA layer includes irradiating a light to the first PSA layer.

10. The method of claim 9, further comprising:
separating the plurality of chip mounting regions by expanding the wafer along a horizontal direction after grinding the wafer.

11. A method of manufacturing a semiconductor package, the method comprising:
attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape including a first pressure sensitive adhesive (PSA) layer attached on the first surface of the wafer and a second PSA layer sequentially stacked on the first PSA layer in a vertical direction, the first PSA layer having a first adhesive strength and a first stiffness, and the second PSA layer having a second adhesive strength less than the first adhesive strength and a second stiffness greater than the first stiffness;
forming a reforming portion by irradiating a laser onto the scribe lane region of the wafer; and
grinding the second surface of the wafer.

12. The method of claim 11, further comprising:
debonding the protective tape from the wafer by curing the first PSA layer,
wherein curing the first PSA layer includes irradiating a light to the first PSA layer.

13. The method of claim 12, further comprising:
separating the wafer into the plurality of chip mounting regions by expanding the wafer along a horizontal direction.

14. The method of claim 11, wherein the first PSA layer has a first thickness, and the second PSA layer has a second thickness greater than the first thickness.

15. The method of claim 14, wherein the first thickness is within a range of 1 μm to 5 μm, and the second thickness is within a range of 10 μm to 25 μm.

16. The method of claim 11, wherein the second PSA layer includes an isocyanate-based curing agent.

17. The method of claim 16, wherein the second PSA layer includes 0.5% by weight to 5% by weight of the isocyanate-based curing agent based on a total weight of the second PSA layer.

18. The method of claim 11, wherein the first PSA layer has a first elastic modulus, and the second PSA has a second elastic modulus greater than the first elastic modulus.

19. The method of claim 18, wherein the first elastic modulus and the second elastic modulus are each a shear storage modulus, and
wherein the first elastic modulus is within a range of 0.1 kilopascal (kPa) to 10 kPa, and the second elastic modulus is within a range of 100 kPa to 1000 kPa.

20. A method of manufacturing a semiconductor package, the method comprising:
attaching a protective tape onto a first surface of a wafer, the wafer having the first surface and a second surface opposite to the first surface, the first surface including a plurality of chip mounting regions and a scribe lane region surrounding the plurality of chip mounting regions, and the protective tape including a first PSA layer and a second PSA layer sequentially stacked in a vertical direction, the first PSA layer being attached on the first surface of the wafer and having a first adhesive strength, a first stiffness, and a first thickness, the second PSA layer being on the first PSA layer and having a second adhesive strength less than the first adhesive strength, a second stiffness greater than the first stiffness, and a second thickness greater than the first thickness;
forming a reforming portion by irradiating laser on the scribe lane region of the wafer; and
grinding the second surface of the wafer.

21.-29. (canceled)
